(19) United States
(12) Patent Application Publication
(10) Pub. No.: US 2017/0179066 A1
(43) Pub. Date: Jun. 22, 2017

(54) BULK SOLDER REMOVAL ON PROCESSOR PACKAGING

(71) Applicants: Russell S. Aoki, Tacoma, WA (US); John W. Jaeger, Olympia, WA (US); Michael S. Brazel, Fedeal Way, WA (US); Daniel P. Carter, Bainbridge Island, WA (US); Anthony P. Valpiani, Olympia, WA (US); Michael R. Hui, Seattle, WA (US); Rashelle Yee, Dupont, WA (US); Joseph J. Jasniewski, Olympia, WA (US); Shelby A. Ferguson, Lacey, WA (US); Thomas A. Boyd, North Plains, OR (US); Jonathan W. Thibado, Beaverton, OR (US); Penny K. Woodcock, Beaverton, OR (US); Rachel G. Taylor, Dupont, WA (US); Laura S. Mortimer, Lacey, WA (US)

(72) Inventors: Russell S. Aoki, Tacoma, WA (US); John W. Jaeger, Olympia, WA (US); Michael S. Brazel, Fedeal Way, WA (US); Daniel P. Carter, Bainbridge Island, WA (US); Anthony P. Valpiani, Olympia, WA (US); Michael R. Hui, Seattle, WA (US); Rashelle Yee, Dupont, WA (US); Joseph J. Jasniewski, Olympia, WA (US); Shelby A. Ferguson, Lacey, WA (US); Thomas A. Boyd, North Plains, OR (US); Jonathan W. Thibado, Beaverton, OR (US); Penny K. Woodcock, Beaverton, OR (US); Rachel G. Taylor, Dupont, WA (US); Laura S. Mortimer, Lacey, WA (US)

(21) Appl. No.: 14/974,881

(22) Filed: Dec. 18, 2015

(51) Int. Cl. H01L 23/00; B23K 3/02

(52) U.S. Cl. CPC H01L 24/741; H01L 24/98; H01L 24/75; H01L 24/799; H01L 24/80; B23K 3/029; H01L 2224/98; H01L 2224/80012; H01L 2224/80912; H01L 2224/749; H01L 2224/7501; H01L 2224/7999

(57) ABSTRACT

Reflow Grid Array technology may be implemented on an interposer device, where the interposer is placed between a motherboard and a BGA package. The interposer may provide a controlled heat source to reflow solder between the interposer and the BGA package. A technical problem faced by an interposer using RGA technology is solder cleaning and removal when removing a BGA package. Technical solutions described herein provide processes and equipment for bulk solder removal from a BGA package that can be executed in the field.

### TECHNICAL FIELD

Embodiments described herein generally relate to electrical interconnections in electronic devices.

### BACKGROUND

Circuit board assembly includes solder attachment of electronic components and electronic packages. The solder attachment provides both electrical and mechanical continuity. Electronic devices are decreasingly using dual in-line packages (DIP) or flat packages, and increasingly using ball grid array (BGA) packages. Similarly, servers and personal computers are decreasingly using socket packages (e.g., socket processor packages), and increasingly using BGA packages. BGA packages offer advantages over other packages, including reduced costs and lower Z-height attributes. Unlike a socket package that is designed to be inserted and removed without solder, a BGA package is a surface mount technology (SMT) that is soldered onto a motherboard. The soldering requirements of a BGA package require time and technical skill to perform any rework. For example, removal of a BGA may require heating of the BGA and motherboard to reflow the solder and separate the BGA from the motherboard. Further, a technician must remove solder from the motherboard and BGA, and new solder must be applied for any subsequently connected BGA device. It is desirable to improve the use of BGA package technologies while reducing the difficulties associated with BGA package rework.

### BRIEF DESCRIPTION OF THE DRAWINGS

FIGS. 1A-1C are perspective diagrams of an RGA configuration, in accordance with at least one embodiment of the invention.

FIG. 2 is a block diagram of an RGA cross-section, in accordance with at least one embodiment of the invention.

FIG. 3 is a block diagram of a reflowed RGA cross-section, in accordance with at least one embodiment of the invention.

FIG. 4 is a perspective diagram of a flexible mechanical solder removal device, in accordance with at least one embodiment of the invention.

FIGS. 5A-5B are perspective diagrams of a flexible mechanical solder vacuum device, in accordance with at least one embodiment of the invention.

FIG. 6 is a perspective diagram of a solder removal mask system, in accordance with at least one embodiment of the invention.

FIG. 7 is a block diagram of a mesh solder removal device, in accordance with at least one embodiment of the invention.

FIGS. 8A-8D are perspective diagrams of a manual mesh solder removal device, in accordance with at least one embodiment of the invention.

FIG. 9 is a perspective diagram of a wicking pad fixture, in accordance with at least one embodiment of the invention.

FIG. 10 is a block diagram of an electronic device that may use a solder rework apparatus or method in accordance with at least one embodiment of the invention.

### DESCRIPTION OF EMBODIMENTS

Reflow Grid Array (RGA) is a technology that provides technical solutions to technical problems facing BGA packages. RGA technology may be implemented on an interposer device, where the interposer is placed between a motherboard and a BGA package. The interposer may provide a controlled heat source to reflow solder between the interposer and the BGA package. The use of RGA technology in the interposer reduces the technical complexity of this BGA rework, and allows for late attachment or removal of BGA packages. The interposer provides more efficient CPU replacement and upgradability, such as allowing swapping processors during validation. The interposer also reduces costs associated with BGA package inventory management (e.g., stock-keeping unit (SKU) management, scrap electronics. The interposer provides several advantages over socket packaging, including lower cost, reduced power loss, lower load force, reduced height requirements, improved signal integrity, and others advantages.

A technical problem faced by an interposer using RGA technology is solder cleaning and removal when removing a BGA package. Technical solutions described herein provide processes and equipment for bulk solder removal from a BGA package that can be executed in the field (e.g., a non-factory setting).

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

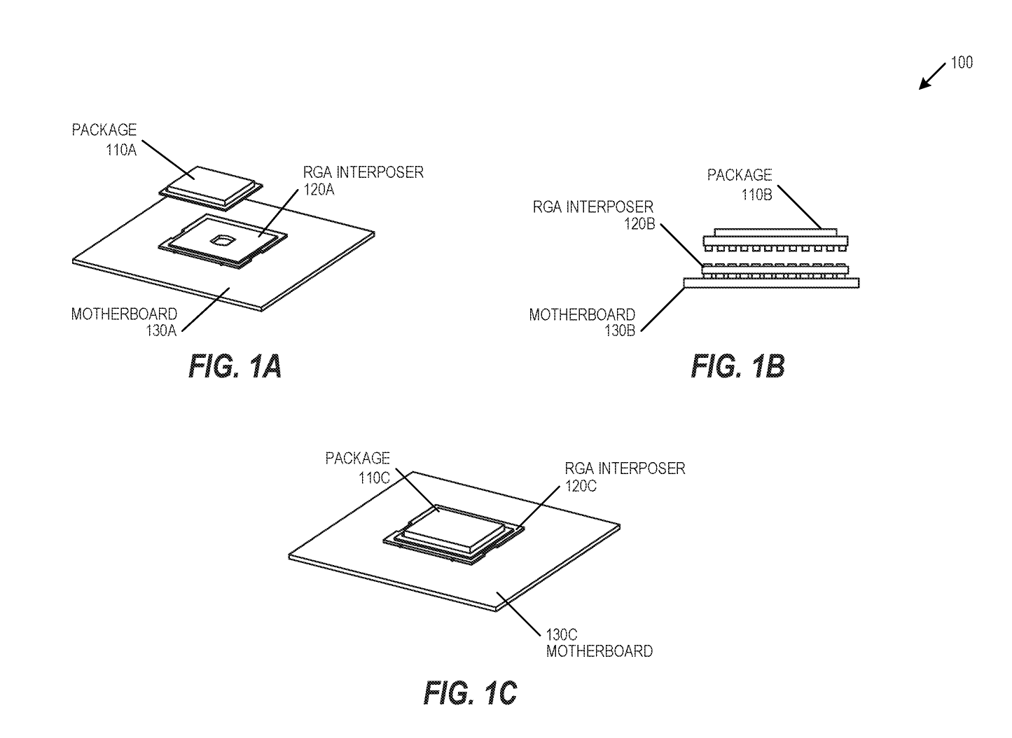

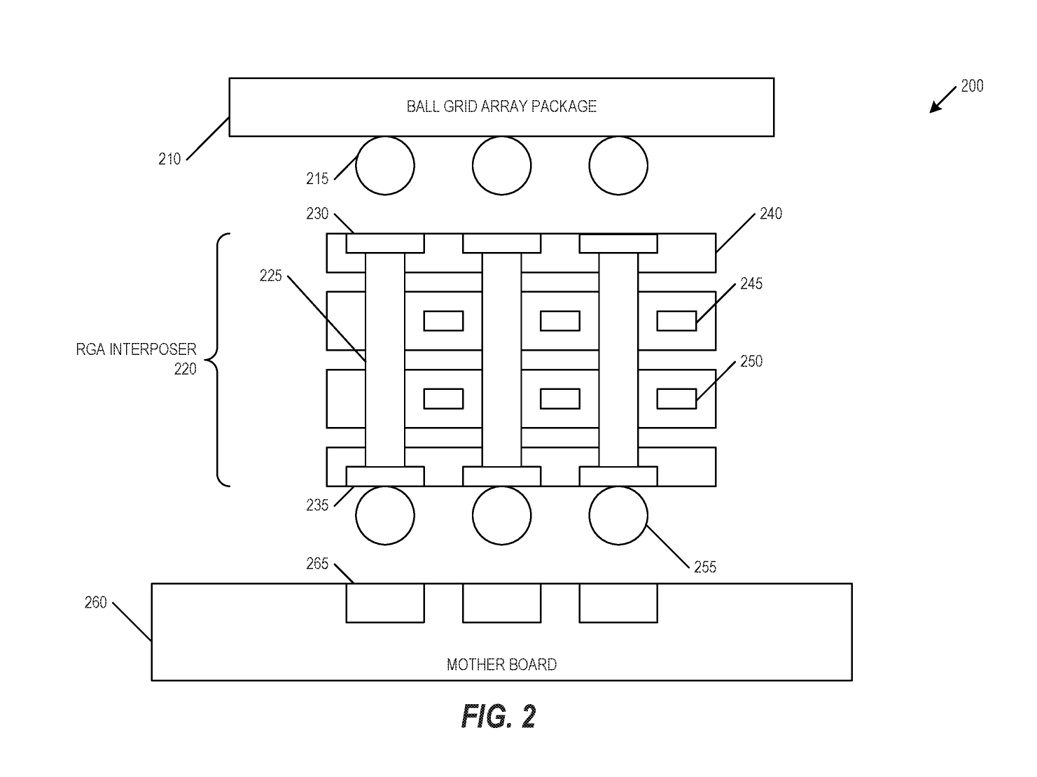

FIGS. 1A-1C are perspective diagrams of an RGA configuration 100, in accordance with at least one embodiment of the invention. FIG. 1A shows a separate BGA package 110A, an RGA interposer 120A, and a motherboard 130A. As shown in FIG. 1B, the RGA interposer 120B is attached to motherboard 130B, and provides an electrical conduit between contacts on the BGA package 110B and contacts on the motherboard 130B. The RGA interposer 120B may be soldered to the motherboard 130B by using the RGA interposer 120B to reflow solder between the RGA interposer 120B and the motherboard 130B. External heat may be provided to reflow solder between the RGA interposer 120B and the motherboard 130B. The RGA interposer 120B may be manufactured as a part of motherboard 130B. As shown in FIG. 1C, to attach the BGA package 130C, the BGA package 130C is placed on the interposer 120C. The RGA interposer 120C locally heats to reflow solder balls and attach the BGA package 130C to the interposer 120C. A cross-section of this RGA configuration 100 is shown in FIG. 2.

FIG. 2 is a block diagram of an RGA cross-section 200, in accordance with at least one embodiment of the invention. The RGA cross-section 200 includes a BGA package 210, an RGA interposer 220, and a motherboard 260. The interposer 220 includes at least one plated through-hole 225 that provides an electric connection between the top and bottom of the interposer. The plated through hole 225 is connected to a BGA-side pad 230 and a motherboard pad 235. The plated through hole spans through at least one interposer dielectric layer 240. An interposer dielectric layer 240 includes a heater trace 245. The heater trace 245 may include a copper trace, or other heat-conductive material. An interposer dielectric layer 240 includes a thermal sensor trace 250. The thermal sensor trace 250 may be on the same interposer dielectric layer 240 as the heater trace 245, or may be on a different interposer dielectric layer 240. The heater trace 245 provides heat to reflow solder. In an example, the heater trace 245 reflows BGA solder balls 215 on the BGA package 210, where the solder balls 215 attach contacts on the BGA package 210 to BGA-side pads 230. The heater trace 245 reflows interposer solder balls 255 on the bottom of the interposer 220, where the interposer solder balls 255 attach the motherboard pads 235 to the motherboard contacts 265. The heater trace 245 and sensor trace 250 may be connected to an external controller, where the external controller may be used to control the heater current while monitoring surface temperatures. Multiple heater traces 245 and sensor traces 250 may be used to control heat to specific zones on the interposer, where the specific zones may be used to reflow a portion of the adjacent solder balls. The interposer may be used in joining or separating a BGA package from the interposer, or in joining or separating the interposer from the motherboard.

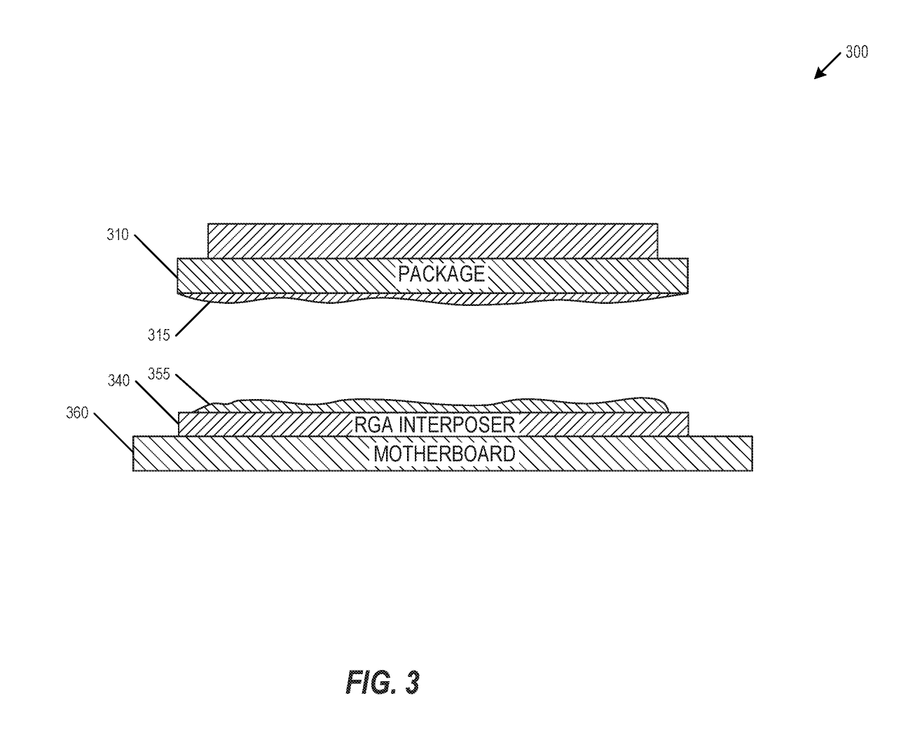

FIG. 3 is a block diagram of a reflowed RGA cross-section 300, in accordance with at least one embodiment of the invention. A heater trace within the RGA interposer 340 reflows solder between the package 310 and the RGA interposer 340. Once the solder has been reflowed, the package 310 is separated from the RGA 355 and the motherboard 360. Once separated, a layer of package solder 315 and a layer of RGA solder 355 may remain. As described above, a technical problem faced by an interposer using RGA technology is solder cleaning and removal when separating the BGA package. Technical solutions for bulk solder removal from a BGA package are described below.

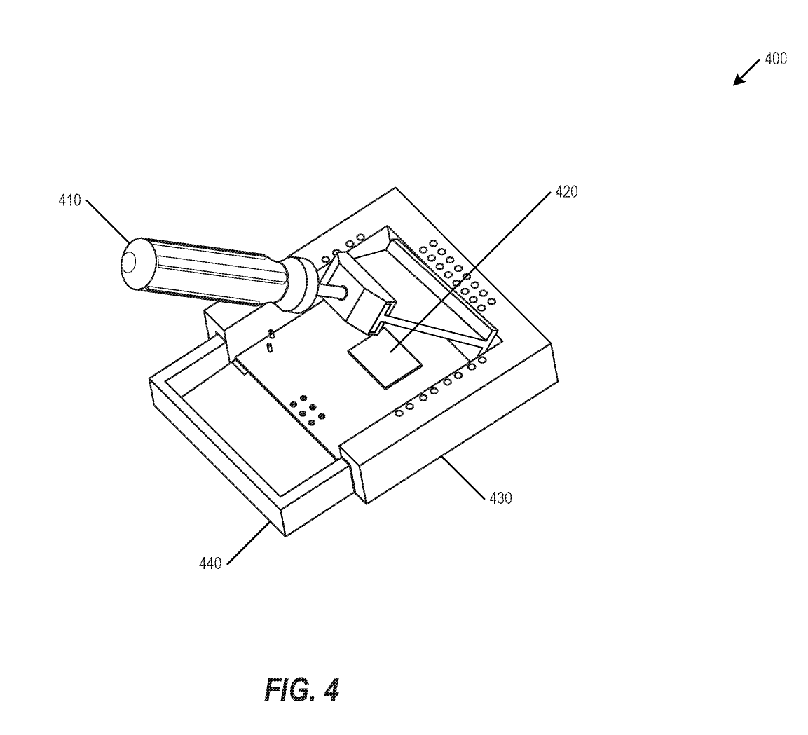

FIG. 4 is a perspective diagram of a flexible mechanical solder removal device 400, in accordance with at least one embodiment of the invention. System 400 includes a flexible mechanical solder removal device 410 that may include a flexible blade (e.g., a solder squeegee). The flexible tool 410 is swiped across the surface of an interposer 420 to sweep the reflowed solder off the interposer. Sweeping the flexible tool 410 is across the surface of the interposer 420 may remove all solder from the interposer 420, or it may provide a uniform residual solder content on the interposer 420. System 400 may include a housing 430 to maintain the position of the interposer 420 or any attached motherboard. The housing 430 may include a removable solder container 440 that catches solder as the solder is swept from the interposer 420.

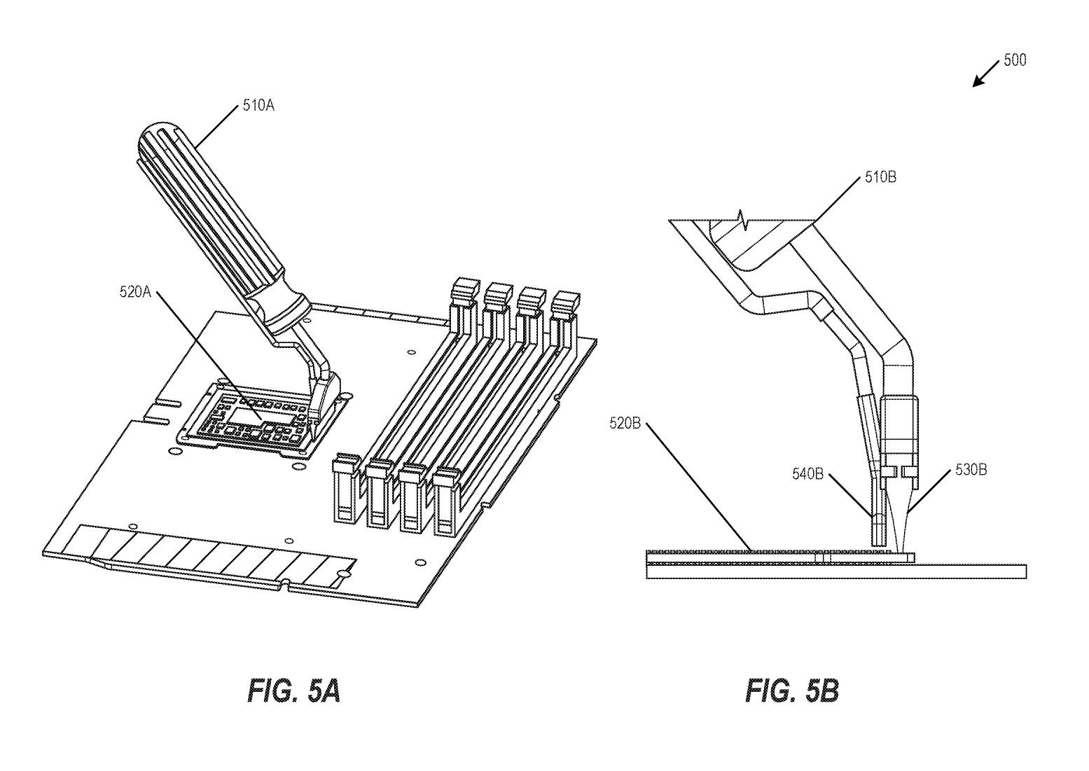

FIGS. 5A-5B are perspective diagrams of a flexible mechanical solder vacuum device 500, in accordance with at least one embodiment of the invention. System 500 includes a flexible mechanical solder vacuum tool 510A and 510B. As shown in FIG. 5B, vacuum tool 510B includes a flexible blade 530B (e.g., solder squeegee) and a solder vacuum 540B. A heater trace within the interposer 520B is used to reflow solder, and the flexible blade 530B is swept across the surface of an interposer 520B to direct solder toward the solder vacuum 540B. The solder vacuum 540B applies suction to remove the solder from the surface of the interposer. The flexible blade 530B and solder vacuum 540B may remove all solder from the interposer 520B, or it may provide a uniform residual solder content on the interposer 520B. The flexible blade 530B may be shaped to direct solder toward the solder vacuum 540B, such as providing a curved shape or curved edges. Similarly, the solder vacuum 540B may be shaped to receive solder from the flexible blade 530B, such as using a wide nozzle or using a blade-shaped nozzle. The solder vacuum 540B may include one or more heating elements to reduce solder clogging, and may include a controller or temperature sensor to maintain

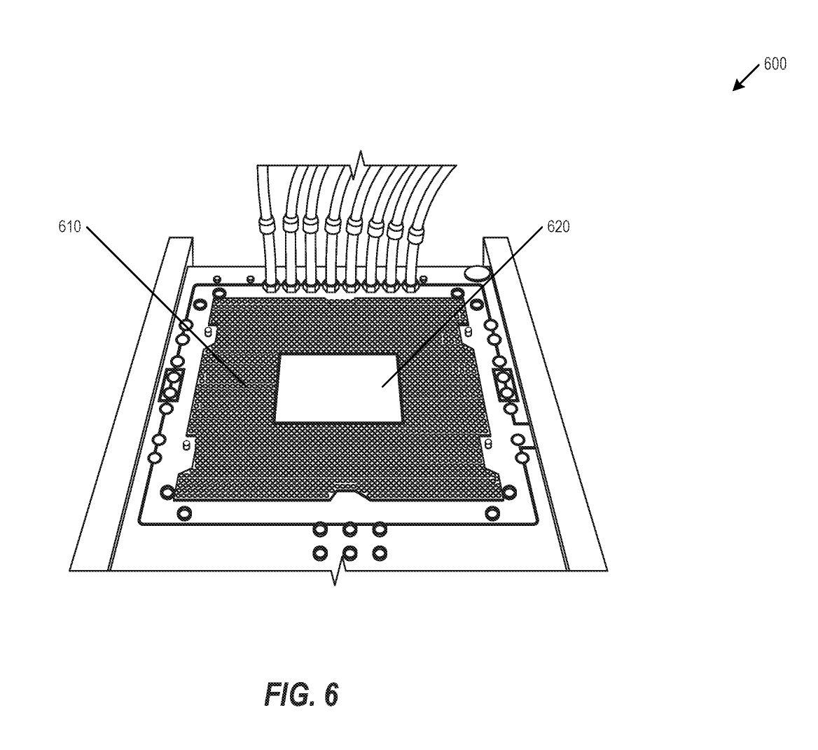

FIG. 6 is a perspective diagram of a solder removal mask system 600, in accordance with at least one embodiment of the invention. System 600 may include a solder removal mask 610, where the mask 610 surrounds and isolates an interposer 620 during removal of the solder. In addition, a component cap may be placed on the interposer to reduce an amount of removed solder introduced into neighboring components while removing solder.

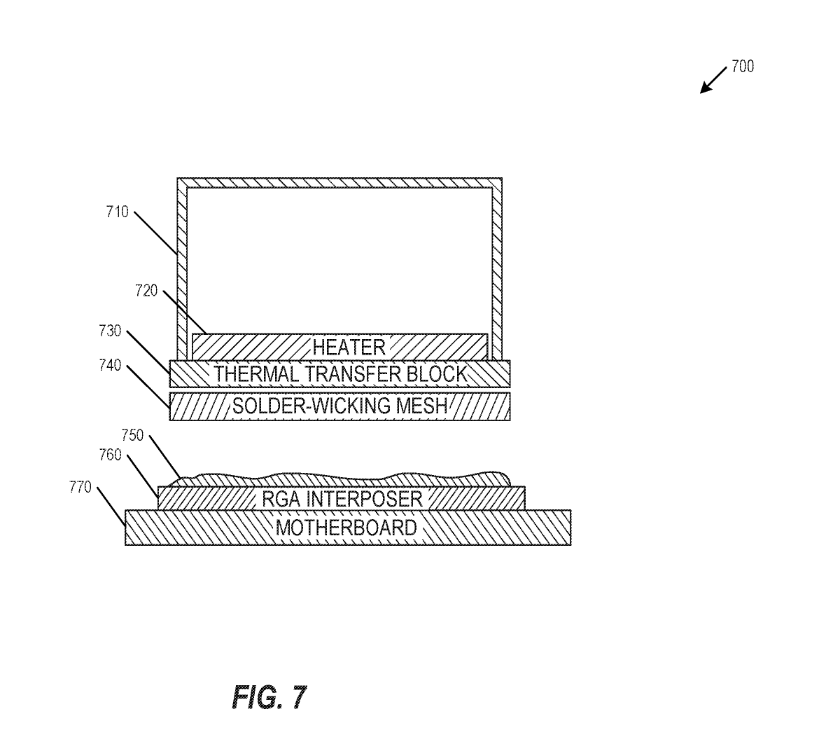

FIG. 7 is a block diagram of a mesh solder removal device 700, in accordance with at least one embodiment of the invention. The mesh tool 700 includes a tool housing 710, a heater 720, and solder-wicking mesh 740 (e.g., solder-wicking pad). A heater trace within RGA interposer 760 reflows solder 750 on the surface of the RGA interposer 760. To remove the reflowed solder, the heater 720 heats the solder-wicking mesh 740, and the heated solder-wicking mesh is applied to the reflowed solder 750 on the RGA interposer 760. As the solder-wicking mesh 740 is applied, the solder 750 is wicked onto the surfaces of the solder-wicking mesh 740 via capillary action. The heater 720 applies heat to the solder-wicking mesh 740 to reduce the probability that the solder will solidify on the solder-wicking mesh, and to increase the capillary wicking of the solder-wicking mesh 740. The porosity of the solder-wicking mesh 740 is selected to increase surface area to improve wicking via capillary action. A multiple layer solder-wicking mesh 740 may be used to increase surface area and improve wicking. In various embodiments, a capillary plate may be used in addition to or instead of a solder-wicking mesh 740 to provide solder removal via capillary action. Solder-wicking mesh 740 may be comprised of copper, as copper offers desirable mesh properties such as ductility and thermal conductivity, however other materials may be used for the solder-wicking mesh 740. Solder-wicking mesh 740 may include a coating of flux, such as rosin flux. The mesh tool 700 may also include a thermal transfer block 730 to improve or regulate heat transfer between the heater 720 and the solder-wicking mesh 740. The thermal transfer block 730 may be a copper block or other thermally conductive material.

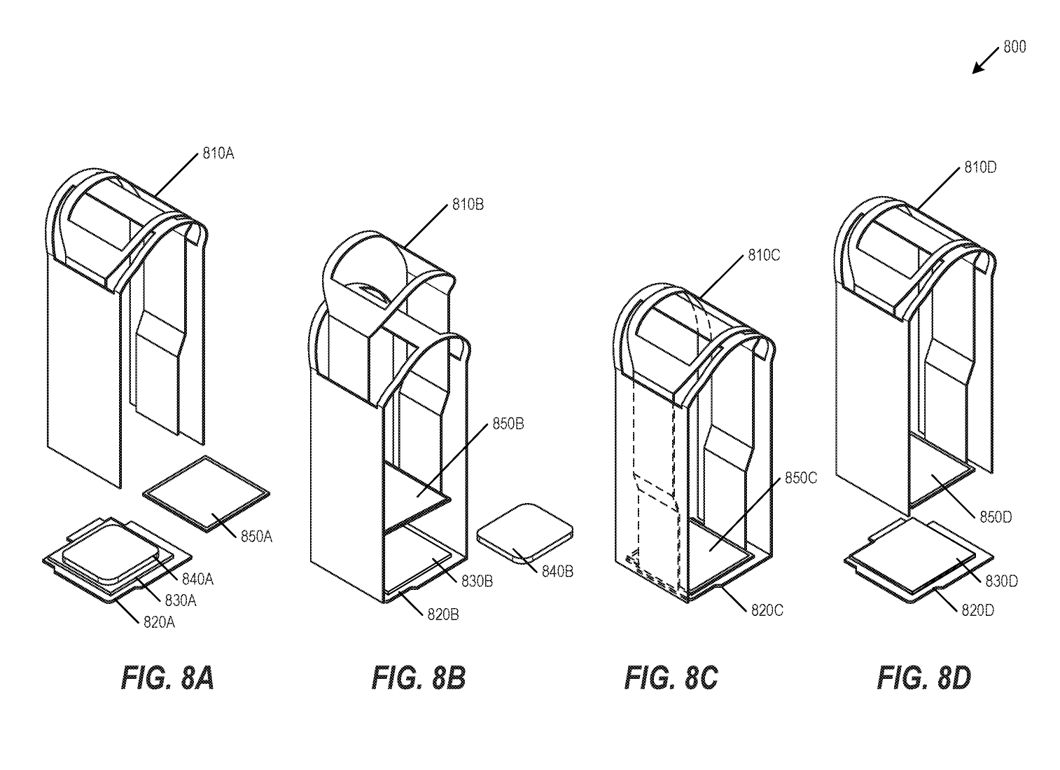

FIGS. 8A-8D are perspective diagrams of a manual mesh solder removal device 800, in accordance with at least one embodiment of the invention. FIG. 8A shows components of the manual tool 800, including a housing 810A, a motherboard 820A, an interposer 830A, a BGA package 840A, and a solder-wicking mesh 850A. FIG. 8B shows solder-wicking mesh 850B placed within the housing 810B, and the motherboard 820B and interposer 830B placed within the housing 810B. A heater trace within interposer 830B reflows solder on the surface of the interposer 830B. FIG. 8C shows the housing 810C and solder-wicking mesh 850C lowered onto the motherboard 820C and interposer 830C to wick solder. FIG. 8D shows the housing 810D and solder-wicking mesh 850D lifted from the motherboard 820D and interposer 830D. The solder-wicking mesh 850D may be reused, or may be separated from the housing 810D and discarded. A capillary plate may be used in addition to or instead of a solder-wicking mesh 850C to wick solder via capillary action. Housing 830D may include a heating element to heat the solder-wicking mesh 850D to increase capillary wicking and to reduce the probability that the solder will solidify on the solder-wicking mesh 850D. Housing 830D may include a power source to provide power to a housing heating element or interposer heating traces. Housing 830D may include a controller to maintain a solder reflow temperature of a housing heating element or interposer heating traces.

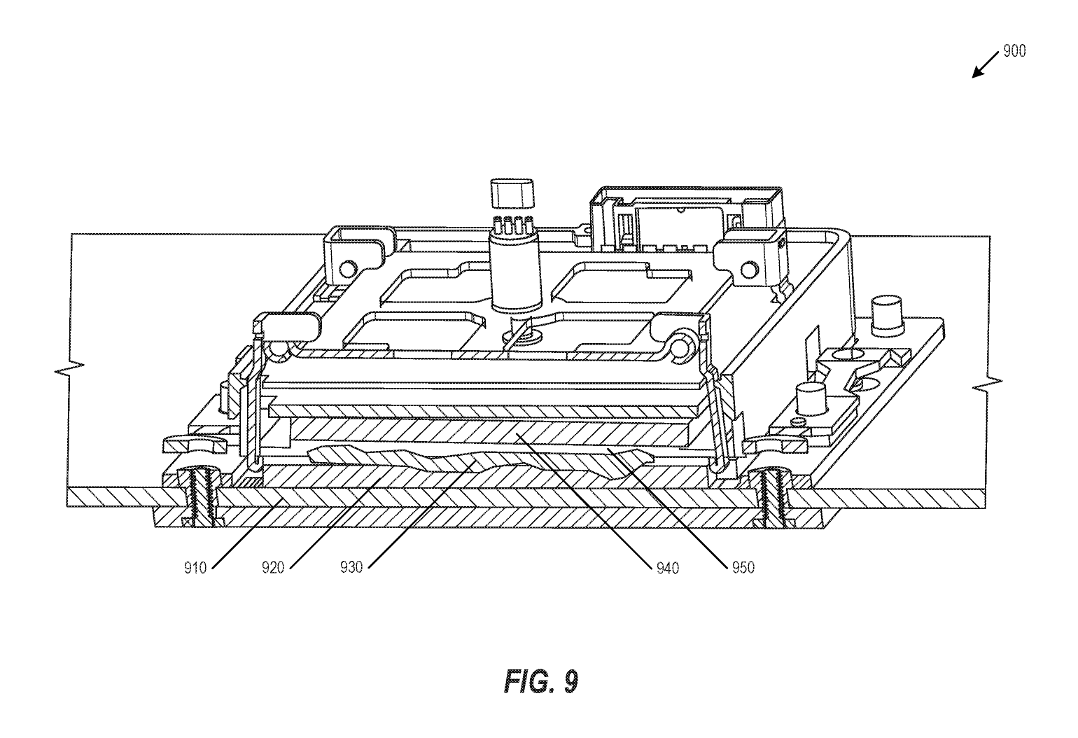

FIG. 9 is a perspective diagram of a wicking pad fixture 900, in accordance with at least one embodiment of the invention. The motherboard 910 and RGA interposer 920 is positioned within the wicking pad fixture 900. A heater trace within the interposer 920 reflows a layer of solder 930. The wicking pad fixture 900 includes a heating element 940 and a capillary plate or solder-wicking mesh 950 for wicking solder. The wicking pad fixture 900 lowers the heating element 940 and solder-wicking mesh 950 onto the interposer 920 to wick the reflowed solder 930. The wicking pad fixture 900 raises the heating element 940 and solder-wicking mesh 950 to remove the wicked solder from the interposer 920. The wicking pad fixture 900 may include a power source to provide power to the heating element 940 or interposer 920, and may include a controller to maintain a solder reflow temperature of the heating element 940 or interposer 920 heating traces.

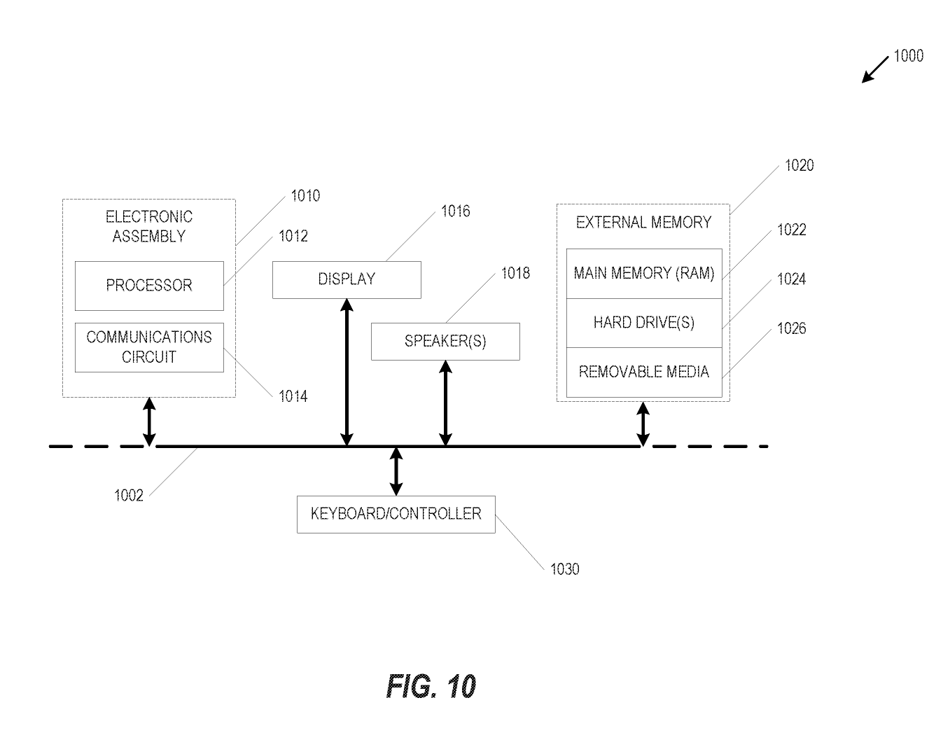

FIG. 10 is a block diagram of an electronic device 1000 that may use a solder rework apparatus or method in accordance with at least one embodiment of the invention. FIG. 10 is included to show an example of a higher-level device application for the present invention. The electronic device 1000 may be used to automate any of the solder rework apparatuses or methods described above. Examples of electronic devices 1000 include, but are not limited to personal computers, tablet computers, mobile telephones, game devices, MP3 or other digital music players, etc. In this example, electronic device 1000 comprises a data processing system that includes a system bus 1002 to couple the various components of the system. System bus 1002 provides communications links among the various components of the electronic device 1000 and can be implemented as a single bus, as a combination of busses, or in any other suitable manner

An electronic assembly 1010 is coupled to system bus 1002. The electronic assembly 1010 can include any circuit or combination of circuits. In one embodiment, the electronic assembly 1010 includes a processor 1012 that can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic assembly 1010 are a custom circuit, an application-specific integrated circuit (ASIC), or the like, such as, for example, one or more circuits (such as a communications circuit 1014) for use in wireless devices like mobile telephones, personal data assistants, portable computers, two-way radios, and similar electronic systems. The IC can perform any other type of function.

The electronic device 1000 can also include an external memory 1020, which in turn can include one or more memory elements suitable to the particular application, such as a main memory 1022 in the form of random access memory (RAM), one or more hard drives 1024, and/or one or more drives that handle removable media 1026 such as compact disks (CD), flash memory cards, digital video disk (DVD), and the like.

The electronic device 1000 can also include a display device 1016, one or more speakers 1018, and a keyboard and/or controller 1030, which can include a mouse, trackball, touch screen, voice-recognition device, or any other device that permits a system user to input information into and receive information from the electronic device 1000.

To better illustrate the method and apparatuses disclosed herein, a non-limiting list of embodiments is provided here:

Example 1 is a method comprising: reflowing a solder on a reflow grid array (RGA) interposer; separating a soldered component from the RGA interposer; and removing the solder from the RGA interposer.

In Example 2, the subject matter of Example 1 optionally includes wherein the RGA interposer is disposed between the soldered component and a circuit board.

In Example 3, the subject matter of Example 2 optionally includes wherein the soldered component includes a ball grid array (BGA).

In Example 4, the subject matter of any one or more of Examples 2-3 optionally include wherein the RGA interposer provides an electrical connection between the circuit board and the soldered component.

In Example 5, the subject matter of any one or more of Examples 1-4 optionally include wherein reflowing the solder on the RGA interposer includes heating the RGA interposer.

In Example 6, the subject matter of Example 5 optionally includes wherein reflowing the solder on the RGA interposer includes applying power to an interposer heating element within the RGA interposer.

In Example 7, the subject matter of any one or more of Examples 1-6 optionally include wherein removing the solder from the RGA interposer includes swiping a solder squeegee across the RGA interposer.

In Example 8, the subject matter of Example 7 optionally includes wherein removing the solder from the RGA interposer includes placing a mask on the RGA interposer to surround and isolate the RGA interposer.

In Example 9, the subject matter of any one or more of Examples 7-8 optionally include wherein swiping the solder squeegee across the RGA interposer includes swiping a solder vacuum across the RGA interposer.

In Example 10, the subject matter of Example 9 optionally includes wherein swiping the solder vacuum across the RGA interposer includes heating the solder vacuum to reduce solder vacuum clogging.

In Example 11, the subject matter of any one or more of Examples 9-10 optionally include wherein the solder vacuum includes a solder vacuum nozzle, and wherein the solder squeegee is shaped to direct solder toward the solder vacuum nozzle.

In Example 12, the subject matter of any one or more of Examples 9-11 optionally include wherein the solder vacuum nozzle includes a wide nozzle solder vacuum.

In Example 13, the subject matter of any one or more of Examples 7-12 optionally include wherein removing the solder from the RGA interposer includes receiving the removed solder in a container.

In Example 14, the subject matter of any one or more of Examples 7-13 optionally include wherein removing the solder from the RGA interposer includes placing a component cap on the RGA interposer to reduce an amount of removed solder introduced into neighboring components.

In Example 15, the subject matter of any one or more of Examples 1-14 optionally include wherein removing the solder from the RGA interposer includes disposing a solder-wicking pad on the RGA interposer.

In Example 16, the subject matter of Example 15 optionally includes wherein disposing the solder-wicking pad includes heating the solder-wicking pad.

In Example 17, the subject matter of Example 16 optionally includes wherein heating the solder-wicking pad includes applying a wicking heating element to a conductive surface disposed between the wicking heating element and the solder-wicking pad.

In Example 18, the subject matter of any one or more of Examples 15-17 optionally include wherein disposing the solder-wicking pad includes wicking the solder from the RGA interposer into the solder-wicking pad, the wicking based on capillary action.

In Example 19, the subject matter of any one or more of Examples 15-18 optionally include wherein the solder-wicking pad includes a copper mesh wicking pad.

In Example 20, the subject matter of any one or more of Examples 15-19 optionally include wherein the solder-wicking pad includes a coating of rosin flux.

Example 21 is a machine-readable medium including instructions, which when executed by a computing system, cause the computing system to perform any of the methods of Examples 1-20.

Example 22 is an apparatus comprising means for performing any of the methods of Examples 1-20.

Example 23 is an apparatus comprising: a reflow grid array (RGA) interposer to reflow solder between the RGA interposer and a soldered component; and a solder removing device to remove solder from the RGA interposer.

In Example 24, the subject matter of Example 23 optionally includes a component removal device to remove the soldered component from the RGA interposer following reflow of the solder.

In Example 25, the subject matter of any one or more of Examples 23-24 optionally include wherein the RGA interposer is disposed between the soldered component and a circuit board.

In Example 26, the subject matter of Example 25 optionally includes wherein the soldered component includes a ball grid array (BGA).

In Example 27, the subject matter of any one or more of Examples 25-26 optionally include wherein the RGA interposer provides an electrical connection between the circuit board and the soldered component.

In Example 28, the subject matter of any one or more of Examples 23-27 optionally include wherein the RGA interposer includes an interposer heating element to reflow the solder.

In Example 29, the subject matter of any one or more of Examples 23-28 optionally include wherein the solder removing device includes a solder squeegee, wherein removing the solder from the RGA interposer includes swiping the solder squeegee across the RGA interposer.

In Example 30, the subject matter of Example 29 optionally includes a mask to surround and isolate the RGA interposer during removal of the solder.

In Example 31, the subject matter of any one or more of Examples 29-30 optionally include wherein the solder removing device further includes a solder vacuum to vacuum reflowed solder from the RGA interposer.

In Example 32, the subject matter of Example 31 optionally includes wherein the solder vacuum includes a vacuum heating element to reduce solder vacuum clogging.

In Example 33, the subject matter of any one or more of Examples 31-32 optionally include wherein the solder vacuum includes a solder vacuum nozzle, and wherein the solder squeegee is shaped to direct solder toward the solder vacuum nozzle.

In Example 34, the subject matter of any one or more of Examples 31-33 optionally include wherein the solder vacuum nozzle includes a wide nozzle solder vacuum.

In Example 35, the subject matter of any one or more of Examples 29-34 optionally include a container to receive the removed solder.

In Example 36, the subject matter of any one or more of Examples 29-35 optionally include a component cap disposed on the RGA interposer to reduce an amount of removed solder introduced into neighboring components.

In Example 37, the subject matter of any one or more of Examples 23-36 optionally include wherein the solder removing device includes a solder-wicking pad.

In Example 38, the subject matter of Example 37 optionally includes a wicking heating element.

In Example 39, the subject matter of Example 38 optionally includes a conductive surface disposed between the wicking heating element and the solder-wicking pad.

In Example 40, the subject matter of any one or more of Examples 37-39 optionally include wherein the solder-wicking pad is configured to wick the solder from the RGA interposer based on capillary action.

In Example 41, the subject matter of any one or more of Examples 37-40 optionally include wherein the solder-wicking pad includes a copper mesh wicking pad.

In Example 42, the subject matter of any one or more of Examples 37-41 optionally include wherein the solder-wicking pad includes a coating of rosin flux.

Example 43 is at least one machine-readable storage medium, comprising a plurality of instructions that, responsive to being executed with processor circuitry of a computer-controlled device, cause the computer-controlled device to: reflow a solder on a reflow grid array (RGA) interposer; separate a soldered component from the RGA interposer; and remove the solder from the RGA interposer.

In Example 44, the subject matter of Example 43 optionally includes wherein the RGA interposer is disposed between the soldered component and a circuit board.

In Example 45, the subject matter of Example 44 optionally includes wherein the soldered component includes a ball grid array (BGA).

In Example 46, the subject matter of any one or more of Examples 44-45 optionally include wherein the RGA interposer provides an electrical connection between the circuit board and the soldered component.

In Example 47, the subject matter of any one or more of Examples 43-46 optionally include wherein the computer-controlled device reflowing the solder on the RGA interposer includes heating the RGA interposer.

In Example 48, the subject matter of Example 47 optionally includes wherein the computer-controlled device reflowing the solder on the RGA interposer includes applying power to an interposer heating element within the RGA interposer.

In Example 49, the subject matter of any one or more of Examples 43-48 optionally include wherein the computer-controlled device removing the solder from the RGA interposer includes swiping a solder squeegee across the RGA interposer.

In Example 50, the subject matter of Example 49 optionally includes wherein the computer-controlled device removing the solder from the RGA interposer includes placing a mask on the RGA interposer to surround and isolate the RGA interposer.

In Example 51, the subject matter of any one or more of Examples 49-50 optionally include wherein the computer-controlled device swiping the solder squeegee across the RGA interposer includes swiping a solder vacuum across the RGA interposer.

In Example 52, the subject matter of Example 51 optionally includes wherein the computer-controlled device swiping the solder vacuum across the RGA interposer includes heating the solder vacuum to reduce solder vacuum clogging.

In Example 53, the subject matter of any one or more of Examples 51-52 optionally include wherein the solder vacuum includes a solder vacuum nozzle, and wherein the solder squeegee is shaped to direct solder toward the solder vacuum nozzle.

In Example 54, the subject matter of any one or more of Examples 51-53 optionally include wherein the solder vacuum nozzle includes a wide nozzle solder vacuum.

In Example 55, the subject matter of any one or more of Examples 49-54 optionally include wherein the computer-controlled device removing the solder from the RGA interposer includes receiving the removed solder in a container.

In Example 56, the subject matter of any one or more of Examples 49-55 optionally include wherein the computer-controlled device removing the solder from the RGA interposer includes placing a component cap on the RGA interposer to reduce an amount of removed solder introduced into neighboring components.

In Example 57, the subject matter of any one or more of Examples 43-56 optionally include wherein the computer-controlled device removing the solder from the RGA interposer includes disposing a solder-wicking pad on the RGA interposer.

In Example 58, the subject matter of Example 57 optionally includes wherein the computer-controlled device disposing the solder-wicking pad includes heating the solder-wicking pad.

In Example 59, the subject matter of Example 58 optionally includes wherein the computer-controlled device heating the solder-wicking pad includes applying a wicking heating element to a conductive surface disposed between the wicking heating element and the solder-wicking pad.

In Example 60, the subject matter of any one or more of Examples 57-59 optionally include wherein the computer-controlled device disposing the solder-wicking pad includes wicking the solder from the RGA interposer into the solder-wicking pad, the wicking based on capillary action.

In Example 61, the subject matter of any one or more of Examples 57-60 optionally include wherein the solder-wicking pad includes a copper mesh wicking pad.

In Example 62, the subject matter of any one or more of Examples 57-61 optionally include wherein the solder-wicking pad includes a coating of rosin flux.

Example 63 is an apparatus comprising: means for reflowing a solder on a reflow grid array (RGA) interposer; means for separating a soldered component from the RGA interposer; and means for removing the solder from the RGA interposer.

In Example 64, the subject matter of Example 63 optionally includes wherein the RGA interposer is disposed between the soldered component and a circuit board.

In Example 65, the subject matter of Example 64 optionally includes wherein the soldered component includes a ball grid array (BGA).

In Example 66, the subject matter of any one or more of Examples 64-65 optionally include wherein the RGA interposer provides an electrical connection between the circuit board and the soldered component.

In Example 67, the subject matter of any one or more of Examples 63-66 optionally include wherein means for reflowing the solder on the RGA interposer includes means for heating the RGA interposer.

In Example 68, the subject matter of Example 67 optionally includes wherein means for reflowing the solder on the RGA interposer includes means for applying power to an interposer heating element within the RGA interposer.

In Example 69, the subject matter of any one or more of Examples 63-68 optionally include wherein means for removing the solder from the RGA interposer includes means for swiping a solder squeegee across the RGA interposer.

In Example 70, the subject matter of Example 69 optionally includes wherein means for removing the solder from the RGA interposer includes means for placing a mask on the RGA interposer to surround and isolate the RGA interposer.

In Example 71, the subject matter of any one or more of Examples 69-70 optionally include wherein means for swiping the solder squeegee across the RGA interposer includes means for swiping a solder vacuum across the RGA interposer.

In Example 72, the subject matter of Example 71 optionally includes wherein means for swiping the solder vacuum across the RGA interposer includes means for heating the solder vacuum to reduce solder vacuum clogging.

In Example 73, the subject matter of any one or more of Examples 71-72 optionally include wherein the solder vacuum includes a solder vacuum nozzle, and wherein the solder squeegee is shaped to direct solder toward the solder vacuum nozzle.

In Example 74, the subject matter of any one or more of Examples 71-73 optionally include wherein the solder vacuum nozzle includes a wide nozzle solder vacuum.

In Example 75, the subject matter of any one or more of Examples 69-74 optionally include wherein means for removing the solder from the RGA interposer includes means for receiving the removed solder in a container.

In Example 76, the subject matter of any one or more of Examples 69-75 optionally include wherein means for removing the solder from the RGA interposer includes means for placing a component cap on the RGA interposer to reduce an amount of removed solder introduced into neighboring components.

In Example 77, the subject matter of any one or more of Examples 63-76 optionally include wherein means for removing the solder from the RGA interposer includes means for disposing a solder-wicking pad on the RGA interposer.

In Example 78, the subject matter of Example 77 optionally includes wherein means for disposing the solder-wicking pad includes means for heating the solder-wicking pad.

In Example 79, the subject matter of Example 78 optionally includes wherein means for heating the solder-wicking pad includes means for applying a wicking heating element to a conductive surface disposed between the wicking heating element and the solder-wicking pad.

In Example 80, the subject matter of any one or more of Examples 77-79 optionally include wherein means for disposing the solder-wicking pad includes means for wicking the solder from the RGA interposer into the solder-wicking pad, the wicking based on capillary action.

In Example 81, the subject matter of any one or more of Examples 77-80 optionally include wherein the solder-wicking pad includes a copper mesh wicking pad.

In Example 82, the subject matter of any one or more of Examples 77-81 optionally include wherein the solder-wicking pad includes a coating of rosin flux.

These and other examples and features of the present molds, mold systems, and related methods will be set forth in part in the following detailed description. This overview is intended to provide non-limiting examples of the present subject matter—it is not intended to provide an exclusive or exhaustive explanation. The detailed description below is included to provide further information about the present molds, mold systems, and methods.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. In the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A method comprising:
reflowing a solder on a reflow grid array (RGA) interposer;
separating a soldered component from the RGA interposer; and
removing the solder from the RGA interposer.

2. The method of 1, wherein reflowing the solder on the RGA interposer includes heating the RGA interposer.

3. The method of 1, wherein removing the solder from the RGA interposer includes swiping a solder squeegee across the RGA interposer.

4. The method of 3, wherein removing the solder from the RGA interposer includes placing a mask on the RGA interposer to surround and isolate the RGA interposer.

5. The method of 3, wherein swiping the solder squeegee across the RGA interposer includes swiping a solder vacuum across the RGA interposer.

6. The method of 1, wherein removing the solder from the RGA interposer includes disposing a solder-wicking pad on the RGA interposer.

7. The method of 6, wherein disposing the solder-wicking pad includes heating the solder-wicking pad.

8. The method of 7, wherein heating the solder-wicking pad includes applying a wicking heating element to a conductive surface disposed between the wicking heating element and the solder-wicking pad.

9. The method of 6, wherein disposing the solder-wicking pad includes wicking the solder from the RGA interposer into the solder-wicking pad, the wicking based on capillary action.

10. The method of 6, wherein the solder-wicking pad includes a copper mesh wicking pad.

11. An apparatus comprising:
a reflow grid array (RGA) interposer to reflow solder between the RGA interposer and a soldered component; and
a solder removing device to remove solder from the RGA interposer.

12. The apparatus of 11, further including a component removal device to remove the soldered component from the RGA interposer following reflow of the solder.

13. The apparatus of 11, wherein the RGA interposer includes an interposer heating element to reflow the solder.

14. The apparatus of 11, wherein the solder removing device includes a solder squeegee, wherein removing the solder from the RGA interposer includes swiping the solder squeegee across the RGA interposer.

15. The apparatus of 14, further including a mask to surround and isolate the RGA interposer during removal of the solder.

16. The apparatus of 14, wherein the solder removing device further includes a solder vacuum to vacuum reflowed solder from the RGA interposer.

17. The apparatus of 11, wherein the solder removing device includes a solder-wicking pad.

18. The apparatus of 17, further including a wicking heating element.

19. The apparatus of 18, further including a conductive surface disposed between the wicking heating element and the solder-wicking pad.

20. The apparatus of 17, wherein the solder-wicking pad includes a copper mesh wicking pad.
